(19) United States
(12) Patent Application Publication
(10) Pub. No.: US 2009/0289278 A1
(43) Pub. Date: Nov. 26, 2009

(54) SEMICONDUCTOR DEVICE AND METHOD FOR MANUFACTURING THE SAME

(75) Inventor: Katsuyuki TORII, Saitama (JP)

Correspondence Address: WILMERHALE/DC, 1875 PENNSYLVANIA AVE., NW, WASHINGTON, DC, 20006, US

(73) Assignee: SANKEN ELECTRIC CO., LTD., Saitama-Ken (JP)

(21) Appl. No.: 12/470,758

(22) Filed: May 22, 2009

(30) Foreign Application Priority Data
May 26, 2008 (JP) 2008-136474

(51) Int. Cl. H01L 29/739; H01L 21/331

(52) U.S. Cl. 257/139; 438/138; 257/E29.198; 257/E21.383

(57) ABSTRACT

A semiconductor device includes: a collector layer of a first conductivity type; a semiconductor area of a second conductivity type formed on the collector layer; a base layer of the first conductivity type formed on the semiconductor area; an emitter layer of the second conductivity type formed in an island shape on the base layer; an insulation film formed on the semiconductor area, the base layer and the emitter layer; a gate electrode formed on the insulation film; an emitter electrode formed on the base layer and the emitter layer; a collector electrode formed on the collector layer; and a crystal defect area of the first conductivity type locally formed in the collector layer. A position of a defect concentration peak of the crystal defect area is in the collector layer. An edge of the crystal defect area adjoins the semiconductor area or is located in the semiconductor area.

This application claims priority from Japanese Patent Application No. 2008-136474 filed on May 26, 2008, the entire subject matter of which is incorporated herein by reference.

### BACKGROUND OF THE INVENTION

1. Field of the Invention

The invention relates to a structure of an IGBT that is an insulated-gate semiconductor element as well as to a method for manufacturing the same.

2. Description of the Related Art

An insulated-gate bipolar transistor is called an IGBT and known as a power semiconductor element that simultaneously implements high-speed operation of an MOSFET and low ON-resistance of the bipolar transistor.

JP-A-4-269874 discloses one example of related art n-channel IGBT. The related art IGBT includes a low lifetime layer in order to inhibit implantation of carrier from a collector layer at the time of operation of the IGBT, thereby contributing speedup of the IGBT; namely, a decrease in a turn-off time.

FIG. 4 is a side cross-sectional view of the related art IGBT 200 having a trench structure.

The related art IGBT 200 includes a semiconductor layer 10 including a p⁺-type collector layer 1, an n⁺-type buffer layer 2, an n⁻-type drift layer 3, a p-type base layer 4, and an n⁺-type emitter layer 5. The related art IGBT 200 also includes trenches 6 formed so as to reach the inside of the drift layer 3 from a principal surface 11 of the semiconductor layer 10; a gate insulation film 7 and gate electrodes 21 formed in the respective trenches 6; an interlayer insulation film 8 formed on the emitter layer 5 and the gate electrodes 21; emitter electrodes 22 formed on the base layer 4, the emitter layer 5, and the interlayer insulation film 8; and a collector electrode 23 formed on the collector layer 1. A crystal defect area 9 is present on the inside of the collector layer 1.

The crystal defect area 9 in the related art IGBT 200 is made through a process for abrading the principal surface 12 of the semiconductor layer 10, to thus thin the collector layer 1 to; for instance, 140 μm or thereabouts, and a process for implanting ions into the principal surface 12.

In the related art IGBT 200, when a voltage (a forward voltage) that increases an electric potential of the collector electrode 23 is applied between the emitter electrodes 22 and the collector electrode 23 in an ON state in which a voltage that is a predetermined threshold voltage or greater is applied to the gate electrodes 21, electrons implanted from the emitter layer 5 reach the collector layer 23 by way of an inversion layer occurring between the drift layer 3 and the emitter layer 5, whereupon an electric current flows. Moreover, the voltage applied to the gate electrodes 21 is decreased to the predetermined threshold voltage or less, to thereby dissipate the inversion layer, so that the electric current can be shut off.

Incidentally, the concentration of crystal defects achieved in the ion implantation process exhibits a distribution pattern having a predetermined width while the depth of ion implantation is taken as a peak defect concentration. In particular, a width at which the concentration of defects comes to one-half of the peak value is referred to as a half width. In the appended claims and throughout the specification, the crystal defect area 9 is assumed to be made as an area whose width is equal to a half width with an implantation depth being taken as the center. The depth of ion implantation and the half width of the crystal defect layer are determined from implantation energy (an acceleration voltage) and the mass of an ion. For instance, when the semiconductor layer 10 is implanted with helium ions 4He²⁺ to a depth of 50 μm, whereupon the crystal defect area 9 is made to a width of about 6 μm.

FIG. 3A is a partial enlarged side cross-sectional view showing a general IGBT, and FIG. 3B is a diagram showing correlation between the depth “d” of implantation of ions and a turn-off time tf of the IGBT achieved when helium ions are implanted into the semiconductor layer 10. As shown in FIG. 3B, there exists a correlation between the implantation depth d and the turn-off time tf of the IGBT. Incidentally, the implantation depth d can also be called the position p of a defect concentration peak in the crystal defect area 9. Therefore, as shown in FIG. 3B, a close relationship can be said to be present between the position p of the defect concentration peak and the turn-off time tf. In order to enhance the turn-off time tf, the position p of the defect concentration peak is desirably within the collector layer 1 in the vicinity of a junction interface 13 between the collector layer 1 and the buffer layer 2. In contrast, when the position p of the defect concentration peak is in the vicinity of the principal surface 12 in the collector layer 1 or in the buffer layer 2, the turn-off time tf is deteriorated. Accordingly, in order to shorten the turn-off time tf and speed up the IGBT, the position p of the defect concentration peak of the crystal defect area 9 is controlled with high accuracy.

However, in the related art IGBT 200, because of variations in processing accuracy of thinning operation performed before ion implantation, difficulty is encountered in controlling the position of the defect concentration peak of the crystal defect area. Further, a thinned wafer is vulnerable to a fracture in manufacturing processes subsequent to the thinning operation. Therefore, the related art IGBT has a drawback of a decrease in yield.

### SUMMARY OF THE INVENTION

The invention aims at producing an IGBT, which can readily achieve a superior turn-off time and a low ON voltage, at superior yield.

According to a first aspect of the invention, there is provided a semiconductor device comprising: a collector layer of a first conductivity type; a semiconductor area of a second conductivity type formed on the collector layer; a base layer of the first conductivity type formed on the semiconductor area; an emitter layer of the second conductivity type formed in an island shape on the base layer; an insulation film formed on the semiconductor area, the base layer and the emitter layer; a gate electrode formed on the insulation film; an emitter electrode formed on the base layer and the emitter layer; a collector electrode formed on the collector layer; and a crystal defect area of the first conductivity type locally formed in the collector layer, wherein a position of a defect concentration peak of the crystal defect area is in the collector layer, and wherein an edge of the crystal defect area adjoins the semiconductor area or is located in the semiconductor area.

According to a second aspect of the invention, in the semiconductor device, wherein the position of the defect concentration peak of the crystal defect area is in a vicinity of a junction interface of the collector layer.

According to a third aspect of the invention, in the semiconductor device, wherein the position of the defect concentration peak of the crystal defect area is in a distance of 3 μm from the junction interface.

According to a fourth aspect of the invention, there is provided a method for manufacturing a semiconductor device, comprising: forming a semiconductor area of a second conductivity type on a collector layer of a first conductivity type; forming a base layer of the first conductivity type on the semiconductor area; forming an emitter layer of the second conductivity type in an island shape on the base layer; forming an insulation film on the semiconductor area, the base layer and the emitter layer; forming a gate electrode on the insulation film; forming an emitter electrode on the base layer and the emitter layer; forming a collector electrode on the collector layer; and forming a crystal defect area of the first conductivity type locally in the collector layer, wherein the crystal defect area is formed by implanting charged particles from the semiconductor layer toward the collector layer.

The aspects of the invention enable high-yield production of an IGBT that simultaneously achieves high speed operation and a decrease in ON voltage.

### BRIEF DESCRIPTION OF THE DRAWINGS

FIG. 1 is a side cross-sectional view of an IGBT according to the invention;

FIGS. 2A to 2D are cross-sectional flowcharts showing a method for manufacturing the IGBT according to the invention;

FIG. 3A is a partial enlarged side cross-sectional view showing a general IGBT, and FIG. 3B is a view showing correlation between the depth of ion implantation and a turn-off time; and

FIG. 4 is a side cross-sectional view of a related art IGBT.

### DETAILED DESCRIPTION OF THE PREFERRED EMBODIMENTS

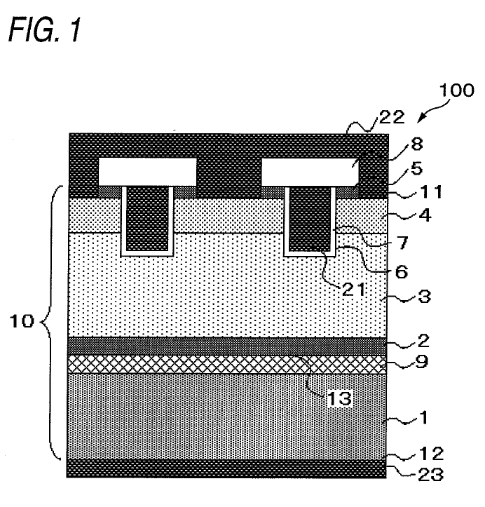

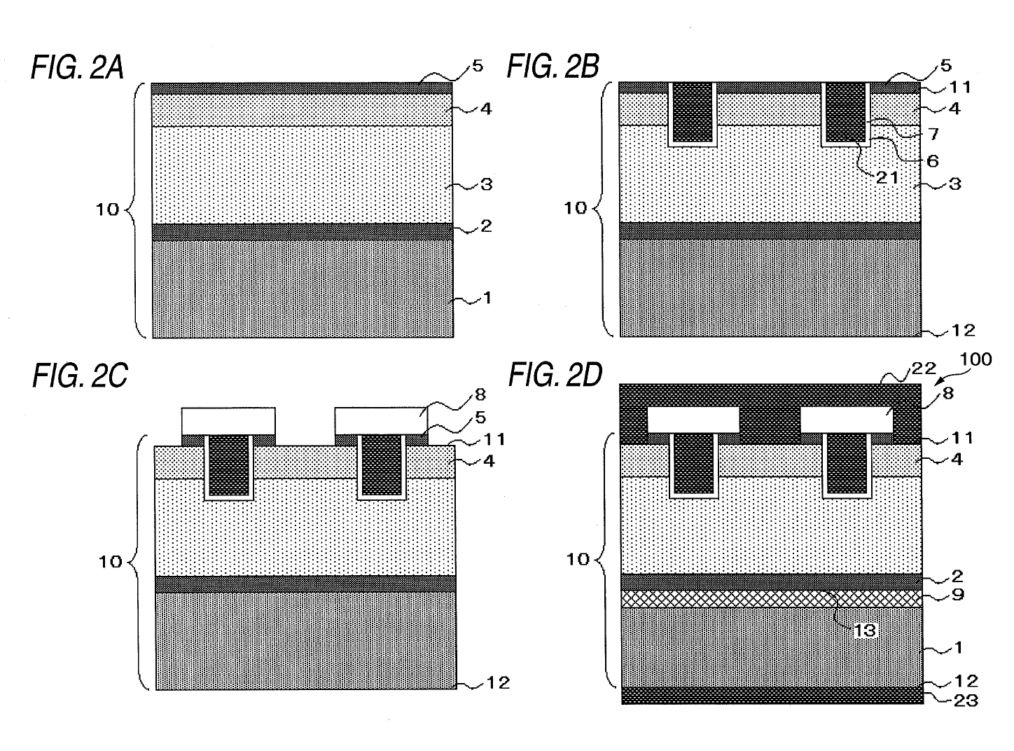

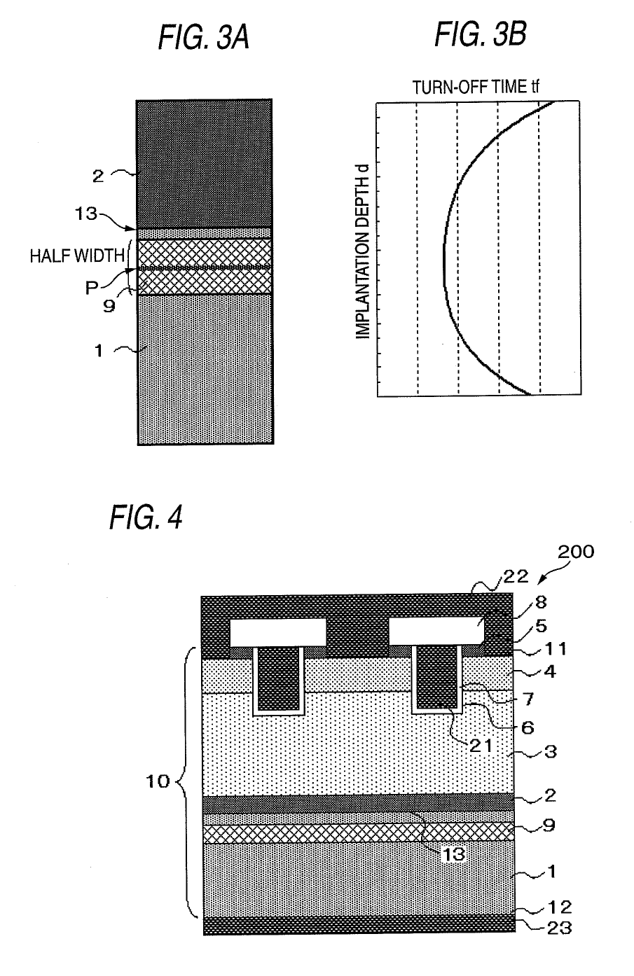

An example IGBT according to an embodiment of the invention will be described with reference to FIGS. 1 and 2. Incidentally, the IGBT is one example of a semiconductor device.

FIG. 1 is a side cross-sectional view of an n-channel IGBT 100 according to an embodiment of the invention.

The IGBT 100 includes a semiconductor layer 10 including a p⁺-type collector layer 1, an n⁺-type buffer layer 2, an n⁻-type drift layer 3, a p-type base layer 4, and an n⁺-type emitter layer 5. The IGBT 100 also includes trenches 6 formed so as to reach the inside of the drift layer 3 from a principal surface 11 of the semiconductor layer 10; a gate insulation film 7 and gate electrodes 21 formed in the respective trenches; an interlayer insulation film 8 formed on the emitter layer 5 and the gate electrodes 21; emitter electrodes 22 formed on the base layer 4, the emitter layer 5, and the interlayer insulation film 8; and a collector electrode 23 formed on the collector layer 1. The IGBT 100 further includes a crystal defect area 9 made in the collector layer 1 so as to adjoin a junction interface 13 between the collector layer 1 and the buffer layer 2.

An example method for manufacturing the IGBT 100 according to the present embodiment of the invention will now be described.

As shown in FIG. 2A, the semiconductor layer 10 in the IGBT 100 can be produced by diffusing phosphor (P) in the p⁺-type collector layer 1, to thus form the n⁺-type buffer layer 2; forming the n⁻-type drift layer 3 on the buffer layer 2 through epitaxial growth; diffusing boron (B) into the drift layer 3, to thus form the p-type base layer 4; and diffusing P into the base layer 4, to thus form the n⁺-type emitter layer 6. In the present embodiment, the buffer layer 2 and the drift layer 3 make up a semiconductor area of the invention. However, the buffer layer 2 may also be omitted. In that case, the drift layer 3 corresponds to the semiconductor area of the invention.

As shown in FIG. 2B, the principal surface 11 of the semiconductor layer 10 is patterned with a mask and subjected to dry etching, such as reactive ion etching (RIE), thereby creating the trenches 6 so as to penetrate through the base layer 4 and the emitter layer 5, to thus reach the drift layer 3. The gate insulation film 7 made of silicon oxide (SiO₂) is formed in the respective trenches 6 by thermal oxidation, and the gate electrodes 21 made of polysilicon are further created in the respective trenches 6 by way of the gate insulation film 7. Subsequently, the principal surface 11 of the semiconductor layer 10 is planarized in an abrasion process, such as chemical-mechanical polishing (CMP). The trenches 6 are created in a stripe, matrix, or dot pattern when viewed in a planer cross section.

As shown in FIG. 2C, the interlayer insulation film 8 made of SiO₂ is formed over the emitter layer 5, the gate insulation film 7, and the gate electrodes 21 by a CVD method. Apertures reaching the base layer 4 are formed in the emitter layer 5, the gate insulation film 7, and the interlayer insulation film 8 by a technique similar to that employed for creating the trenches 6; subsequently, the emitter electrodes 22 made of Aluminum (Al) are evaporated.

As shown in FIG. 2D, irregularities in the emitter electrodes 22 are eliminated in the abrasion process, and Helium (He) ions are implanted into the principal surface 11 of the semiconductor layer 10, thereby creating the crystal defect area 9. The substrate is then subjected to annealing in an inactive gas environment at 250 to 350° C., thereby evaporating the collector electrode 23 made of Al.

In the IGBT 100 according to the present embodiment of the invention, a position p of a defect concentration peak of the crystal defect area 9 is located in the collector layer 1, and an edge of the crystal defect area is formed so as to adjoin the junction interface 13. The edge of the crystal defect area 9 may also be located in the buffer layer 2. So long as the position p of the defect concentration peak is in the collector layer 1 in the vicinity of the junction interface 13; namely, in a distance of 3 μm from the junction interface 13, the turn-off time of the IGBT 100 can be enhanced. Incidentally, if Hydrogen (H) ions are implanted in the collector layer 1 instead of the He ions, the position p of the defect concentration peak is in a distance of 0 μm to 1.5 μm from the junction interface 13.

In relation to the thicknesses of the respective semiconductor layers in the IGBT 100, the collector layer 1 has a thickness of 200 to 300 μm; the buffer layer 2 has a thickness of 5 to 20 μm; and the drift layer 3 has a thickness of 20 to 70 μm. In relation to concentrations of impurities in the respective semiconductor layers, the collector layer 1 has a doping level of 5×10⁷ to 8×10¹⁸ cm⁻³; the buffer layer 2 has a doping level of 5×10¹⁶ to 5×10¹⁸ cm⁻³; and the drift layer 3 has a doping level of 5×10¹³ to 5×10¹⁵ cm⁻³. Further, the amount of He ions implanted ranges from 5×10¹⁰ to 5×10¹² cm⁻².

According to the IGBT 100 of the embodiment of the invention, the position p of the defect concentration peak of the crystal defect area 9 is within the collector layer 1 in the vicinity of the junction interface 13 between the collector layer 1 and the buffer layer 2 (or between the collector layer 1 and the drift layer 3), and hence a superior turn-off time tf and a low ON voltage can be readily achieved. According to the manufacturing method, the crystal defect area 9 is formed by implanting ions into the principal surface 11 of the semiconductor layer 10; and hence, variations in processing accuracy and fracture of a wafer can be prevented, and a production yield of the IGBT 100 can be enhanced. Further, crystal defects, which would be crated even in the drift layer 3, and the like, by ion implantation, can be recovered in the annealing processing following ion implantation; therefore, an IGBT exhibiting a superior characteristic can be produced.

The IGBT of the invention and the method for manufacturing the IGBT are not limited to the embodiment provided above and susceptible to various modifications. For instance, even when the structure and the manufacturing method of the invention are applied to an IGBT not having a trench structure or a p-channel IGBT, similar advantages can be yielded. Moreover, proton or heavy metal ions can also be used for ion implantation. A superior turn-off time can be provided by optimizing an implantation depth. Any condition for an annealing temperature may also be acceptable, so long as unwanted crystal defects caused by ion implantation can be recovered under the condition.

What is claimed is:

1. A semiconductor device comprising:
a collector layer of a first conductivity type;
a semiconductor area of a second conductivity type formed on the collector layer;
a base layer of the first conductivity type formed on the semiconductor area;
an emitter layer of the second conductivity type formed in an island shape on the base layer;
an insulation film formed on the semiconductor area, the base layer and the emitter layer;
a gate electrode formed on the insulation film;
an emitter electrode formed on the base layer and the emitter layer;
a collector electrode formed on the collector layer; and
a crystal defect area of the first conductivity type locally formed in the collector layer,
wherein a position of a defect concentration peak of the crystal defect area is in the collector layer, and
wherein an edge of the crystal defect area adjoins the semiconductor area or is located in the semiconductor area.

2. The semiconductor device according to claim 1,
wherein the position of the defect concentration peak of the crystal defect area is in a vicinity of a junction interface of the collector layer.

3. The semiconductor device according to claim 1,
wherein the position of the defect concentration peak of the crystal defect area is in a distance of 3 μm from the junction interface.

4. A method for manufacturing a semiconductor device, comprising:
forming a semiconductor area of a second conductivity type on a collector layer of a first conductivity type;
forming a base layer of the first conductivity type on the semiconductor area;
forming an emitter layer of the second conductivity type in an island shape on the base layer;
forming an insulation film on the semiconductor area, the base layer and the emitter layer;
forming a gate electrode on the insulation film;
forming an emitter electrode on the base layer and the emitter layer;
forming a collector electrode on the collector layer; and
forming a crystal defect area of the first conductivity type locally in the collector layer,
wherein the crystal defect area is formed by implanting charged particles from the semiconductor layer toward the collector layer.
